(19) United States
(12) Patent Application Publication
(10) Pub. No.: US 2024/0357885 A1
(43) Pub. Date: Oct. 24, 2024

(54) DISPLAY DEVICE

(71) Applicant: Samsung Display Co., Ltd., Yongin-Si (KR)

(72) Inventors: YONGHEE LEE, Yongin-si (KR); JINSEON KWAK, Yongin-si (KR); KYUNG-BAE KIM, Yongin-si (KR); JIHYE LEE, Yongin-si (KR)

(21) Appl. No.: 18/436,022

(22) Filed: Feb. 8, 2024

(30) Foreign Application Priority Data
Apr. 19, 2023 (KR) 10-2023-0051129

(51) Int. Cl. H10K 59/131; H10K 59/121

(52) U.S. Cl. CPC H10K 59/131; H10K 59/1216

(57) ABSTRACT

A display device includes an active pattern disposed on a substrate, a gate electrode disposed on the active pattern, a first connection electrode disposed on and connected to the active pattern, a first electrode line disposed on the first connection electrode, a second electrode line disposed on a same layer as the first electrode line and forming a first capacitor with the first electrode line, a third electrode line disposed on the same layer as the first electrode line and forming a second capacitor with the second electrode line, a first data line disposed on the third electrode line, and a second data line spaced apart from the first data line.

### CROSS-REFERENCE TO RELATED APPLICATIONS

This application claims priority to Korean Pat. App. No. 10-2023-0051129, filed on Apr. 19, 2023, and all the benefits accruing therefrom under 35 U.S.C. § 119, the content of which in its entirety is herein incorporated by reference.

### BACKGROUND

### Field

Embodiments disclosed herein relate generally to a display device. More specifically, embodiments relate to a display device providing visual information.

### Discussion of the Background

A display device is a device that displays an image to provide visual information to a user. Among display devices, organic light emitting diode displays (OLED displays) have been attracting attention and have been used in many different applications. One application is in a head mounted display (HMD) or the like that may be used in virtual reality (VR) or augmented reality (AR). A micro display may be applied in a product such as a head-mounted display. As the micro display, an organic light emitting diode on silicon (OLEDoS) display may be used.

An OLEDoS display may include pixels, each pixel containing an anode electrode, an organic light emitting layer, and a cathode electrode formed on a semiconductor substrate. The semiconductor substrate may include a CMOS circuit for controlling each pixel.

### SUMMARY

Embodiments provide a display device with improved display quality.

A display device according to an embodiment may include an active pattern disposed on a substrate, a gate electrode disposed on the active pattern, a first connection electrode disposed on and connected to the active pattern, a first electrode line disposed on the first connection electrode, a second electrode line disposed on a same layer as the first electrode line and forming a first capacitor with the first electrode line, a third electrode line disposed on the same layer as the first electrode line and forming a second capacitor with the second electrode line, a first data line disposed on the third electrode line, and a second data line spaced apart from the first data line.

In an embodiment, the first data line and the second data line may be on different layers.

In an embodiment, no electrode line may be disposed on the second data line.

In an embodiment, no electrode line may be disposed between the first data line and the second data line.

In an embodiment, the display device may further include a fourth electrode line disposed on the first electrode line, and a MIM (metal-insulator-metal) capacitor between the first electrode line and the fourth electrode line may be formed.

A display device according to another embodiment of the present disclosure may include an active pattern disposed on a substrate, a gate electrode disposed on the active pattern, a first connection electrode disposed on and connected to the active pattern, a 1-1 electrode line disposed on the first connection electrode, a 2-1 electrode line disposed on a same layer as the 1-1 electrode line and forming a first capacitor with the 1-1 electrode line, a first data line disposed on the 2-1 electrode line, a 3-1 electrode line disposed on the first data line, a 2-3 electrode line disposed on a same layer as the 3-1 electrode line and forming a second capacitor with the 3-1 electrode line and a second data line disposed on the 2-3 electrode line.

In an embodiment, the display device may further include a 1-2 electrode line disposed on the 1-1 electrode line and electrically connected to the 1-1 electrode line and a 2-2 electrode line disposed on the 2-1 electrode line, electrically connected to the 2-1 electrode line, and forming a third capacitor with the 1-2 electrode line, the third capacitor being connected in parallel with the first capacitor.

In an embodiment, the first data line may be disposed on a same layer as the 2-2 electrode line.

In an embodiment, the display device may further include a 3-2 electrode line disposed on the 3-1 electrode line and electrically connected to the 3-1 electrode line and a 2-4 electrode line disposed on the 2-3 electrode line, electrically connected to the 2-3 electrode line, and forming a fourth capacitor with the 3-2 electrode line, the fourth capacitor being connected in parallel with the second capacitor.

In an embodiment, the second data line may be disposed on a same layer as the 2-4 electrode line.

In an embodiment, the display device may further include a MIM capacitor between the 1-1 electrode line and the 1-2 electrode line.

A display device according to still another embodiment of the present disclosure may include an active pattern disposed on a substrate, a gate electrode disposed on the active pattern, a first connection electrode disposed on and connected to the active pattern, a 1-1 electrode line disposed on the first connection electrode, a 2-1 electrode line disposed on a same layer as the 1-1 electrode line and forming a 1-1 capacitor with the 1-1 electrode line, a 3-1 electrode line disposed on the 1-1 electrode line, a 2-2 electrode line disposed on a same layer as the 3-1 electrode line, electrically connected to the 2-1 electrode, and forming a 2-1 capacitor with the 3-1 electrode line, a first data line disposed on the 3-1 electrode line, and a second data line disposed apart from the first data line.

In an embodiment, the first data line and the second data line may be on different layers.

In an embodiment, no electrode line may be disposed on the second data line.

In an embodiment, no electrode line may be formed on a layer between the second data line and the first data line.

In an embodiment, the display device may further include a 1-2 electrode line disposed on the 1-1 electrode line and electrically connected to the 1-1 electrode line and a 2-3 electrode line disposed on the 2-1 electrode line and electrically connected to the 2-1 electrode line, and the 1-2 electrode line and the 2-3 electrode line may form a 1-2 capacitor.

In an embodiment, the display device may further include a 3-2 electrode line disposed on the 3-1 electrode line and electrically connected to the 3-1 electrode line and a 2-4 electrode line disposed on the 2-2 electrode line and electrically connected to the 2-2 electrode line, and the 3-2 electrode line and the 2-4 electrode line may form a 2-2 capacitor.

In an embodiment, the first data line may be on a same layer as the 1-2 electrode line.

In an embodiment, the second data line may be on a same layer as the 3-2 electrode line.

In an embodiment, the display device may further include a MIM capacitor between the 1-1 electrode line and the 3-1 electrode line.

Therefore, in a display device according to embodiments of the present disclosure, by disposing the existing data line from a same layer as the connection electrode to the electrode line layer, an interaction with the gate electrode may be reduced to prevent formation of a parasitic capacitor. Accordingly, a charging rate of the capacitor may be secured. In this case, the data line may be spaced apart from the connection electrode by one layer. Through this, it is possible to implement a desired luminance in each pixel when designing a high-speed driving pixel.

### BRIEF DESCRIPTION OF THE DRAWINGS

The accompanying drawings are included to illustrate and provide a further understanding of embodiments that are described in detail below.

FIG. 1 is a plan view illustrating a display device according to an embodiment of the present disclosure.

FIG. 2 is an enlarged plan view of part P of FIG. 1.

FIG. 3 is a circuit diagram illustrating a sub-pixel included in the display device of FIG. 1.

FIG. 4 is a cross-sectional view illustrating a sub-pixel.

FIG. 5 is a plan view illustrating a 1-1 electrode line and a 2-3 electrode line included in the sub-pixel of FIG. 4.

FIG. 6 is a plan view illustrating a 2-1 electrode line and a 3-1 electrode line included in the sub-pixel of FIG. 4.

FIG. 7 is a cross-sectional view illustrating a sub-pixel included in a display device according to an embodiment of the present disclosure.

FIG. 8 is a plan view illustrating a 1-1 electrode line, a 2-1 electrode line, and a 3-1 electrode line included in the sub-pixel of FIG. 7.

FIG. 9 is a plan view illustrating a 1-3 electrode line, a 2-3 electrode line, a 3-3 electrode line, and a first data line included in the sub-pixel of FIG. 7.

FIG. 10 is a plan view illustrating a 1-4 electrode line, a 2-4 electrode line, a 3-4 electrode line, and a second data line included in the sub-pixels of FIG. 7.

FIG. 11 is a cross-sectional view illustrating the sub-pixel included in a display device according to another embodiment of the present disclosure.

FIG. 12 is a plan view illustrating a 1-1 electrode line and a 2-1 electrode line included in the sub-pixel of FIG. 11.

FIG. 13 is a plan view illustrating a 1-2 electrode line, a 2-2 electrode line, and a first data line included in the sub-pixel of FIG. 11.

FIG. 14 is a plan view illustrating a 2-3 electrode line and a 3-1 electrode line included in the sub-pixel of FIG. 11.

FIG. 15 is a plan view illustrating a 2-4 electrode line, a 3-2 electrode line, and a second data line included in the sub-pixel of FIG. 11.

FIG. 16 is a cross-sectional view illustrating a sub-pixel included in a display device according to still another embodiment of the present disclosure.

FIG. 17 is a plan view illustrating a 1-1 electrode line and a 2-1 electrode line included in the sub-pixel of FIG. 16.

FIG. 18 is a plan view illustrating a 2-2 electrode line and a 3-1 electrode line included in the sub-pixel of FIG. 16.

FIG. 19 is a plan view illustrating a 1-2 electrode line, a 2-3 electrode line, and a first data line included in the sub-pixel of FIG. 16.

FIG. 20 is a plan view illustrating a 2-4 electrode line, a 3-2 electrode line, and a second data line included in the sub-pixel of FIG. 16.

FIG. 21 is a cross-sectional view illustrating a sub-pixel included in a display device according to still another embodiment.

FIG. 22 is an enlarged view illustrating first and second MIM capacitors included in the sub-pixel of FIG. 21.

### DETAILED DESCRIPTION

Illustrative, non-limiting embodiments will be more clearly understood from the following detailed description in conjunction with the accompanying drawings.

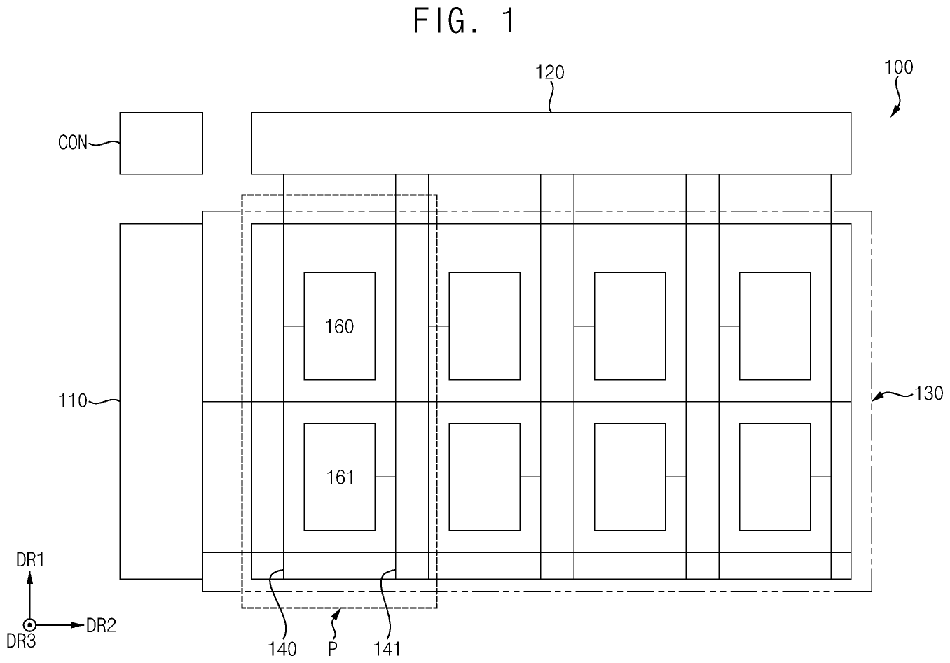

FIG. 1 is a plan view illustrating a display device according to an embodiment of the present disclosure.

Referring to FIG. 1, a display device 100 according to the illustrated embodiment may include a display part 130 and driving parts CON, 110, and 120. The display part 130 may be an area capable of displaying an image by generating light or adjusting a transmittance of light provided from an external light source. The driving parts CON, 110, and 120 may be areas that do not display images. The driving parts CON, 110, and 120 may be located around the display part 130.

In the present specification, a plane may be defined by a first direction DR1 and a second direction DR2 crossing the first direction DR1. For example, the first direction DR1 may be perpendicular to the second direction DR2.

A plurality of sub-pixels 160 and 161 may be disposed in the display part 130. The plurality of sub-pixels 160 and 161 may be arranged in an array or a matrix form having rows extending along the first direction DR1 and columns extending along the second direction DR2. Each of the plurality of sub-pixels 160 and 161 may emit light. As the plurality of sub-pixels 160 and 161 emit light, the display part 130 may display an image.

Lines connected to the plurality of sub-pixels 160 and 161 may also be disposed in the display part 130. For example, the lines in the display part 130 may include a data signal line, a gate signal line, and a power line.

Devices for driving the plurality of sub-pixels 160 and 161 may be disposed in the driving parts CON, 110, and 120. For example, the driving parts CON, 110, and 120 may include a data driving part 120, a gate driving part 110, and a timing controller CON. The plurality of sub-pixels 160 and 161 may emit light based on signals transmitted from the driving parts.

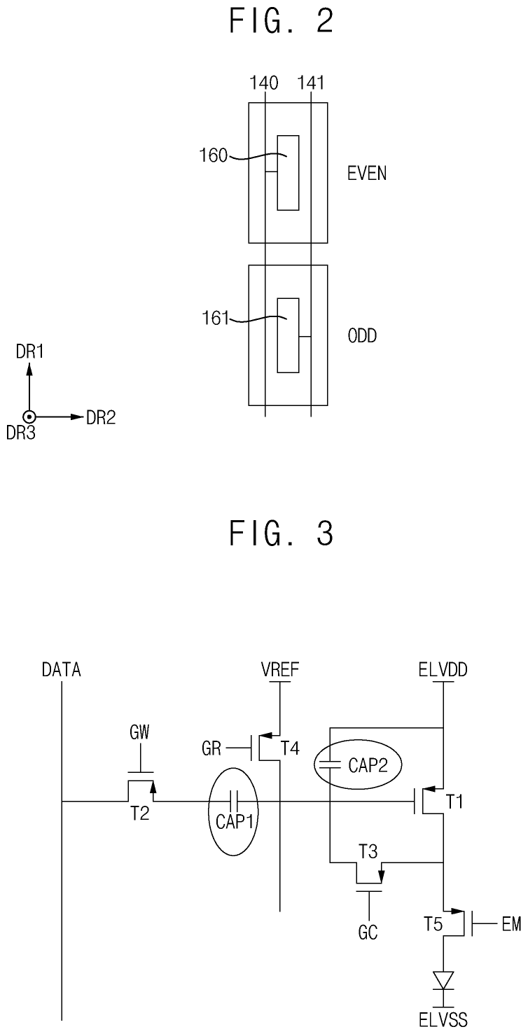

FIG. 2 is an enlarged plan view of part P of FIG. 1.

Referring to FIG. 2, the display device 100 according to an embodiment of the present disclosure may include a first data line 140 and a second data line 141 that respectively apply signals to the sub-pixels 160 and 161. The first data line 140 may transfer a data voltage to the first sub-pixel 160, and the second data line 141 may transfer a data voltage to the second sub-pixel 161.

FIG. 3 is a circuit diagram illustrating a sub-pixel included in the display device of FIG. 1.

Referring to FIGS. 1 to 3, each of the sub-pixels 160 and 161 may include first to fifth transistors T1, T2, T3, T4, and T5, a first capacitor CAP1, and a second capacitor CAP2.

The first transistor T1 may include a gate electrode, a first electrode, and a second electrode. The gate electrode of the first transistor T1 may be connected to the first capacitor CAP1. In another embodiment, the gate electrode of the first transistor T1 may be connected to the second capacitor CAP2, and a first electrode of the third transistor T3. The first electrode of the first transistor T1 may be connected to a second electrode of the third transistor T3 and a second electrode of the fifth transistor T5. A driving voltage ELVDD may be applied to the second electrode of the first transistor T1.

The second transistor T2 may include a gate electrode, a first electrode, and a second electrode. A data write signal GW may be applied to the gate electrode of the second transistor T2. A data voltage DATA may be applied to the first electrode of the second transistor T2. The second electrode of the second transistor T2 may be connected to the first capacitor CAP1.

The third transistor T3 may include a gate electrode, a first electrode, and a second electrode. A compensation gate signal GC may be applied to the gate electrode of the third transistor T3. The second capacitor CAP2 may be connected to the first electrode of the third transistor T3. The second electrode of the third transistor T3 may be connected to the first electrode of the first transistor T1 and a second electrode of the fifth transistor T5.

The fourth transistor T4 may include a gate electrode, a first electrode, and a second electrode. A reference gate signal GR may be applied to the gate electrode of the fourth transistor T4. The first capacitor CAP1 may be connected to the first electrode of the fourth transistor T4. A reference voltage VREF may be applied to the second electrode of the fourth transistor T4.

The fifth transistor T5 may include a gate electrode, a first electrode, and a second electrode. The emission control signal EM may be applied to the gate electrode of the fifth transistor T5. The first electrode of the fifth transistor T5 may be connected to an anode of a light emitting element. The second electrode of the fifth transistor T5 may be connected to the first electrode of the first transistor T1 and the second electrode of the third transistor T3.

The first capacitor CAP1 may include a first electrode and a second electrode. The first electrode of the first capacitor CAP1 may be connected to the second electrode of the second transistor T2. The second electrode of the first capacitor CAP1 may be connected to the gate electrode of the first transistor T1. In another embodiment, the second electrode of the first capacitor CAP1 may be connected to the second capacitor CAP2 or the first electrode of the third transistor T3.

The second capacitor CAP2 may include a first electrode and a second electrode. The driving voltage ELVDD may be applied to the first electrode of the second capacitor CAP2. The second electrode of the second capacitor CAP2 may be connected to the second electrode of the first capacitor CAP1 In another embodiment, the second electrode of the second capacitor CAP2 may be connected to the gate electrode of the first transistor T1, and the first electrode of the third transistors T3.

However, although it has been described that each of the sub-pixels 160 and 161 includes 5 transistors and 2 capacitors, embodiments are not limited thereto. For example, each of the pixels 160 and 161 may include at least one transistor and at least one storage capacitor.

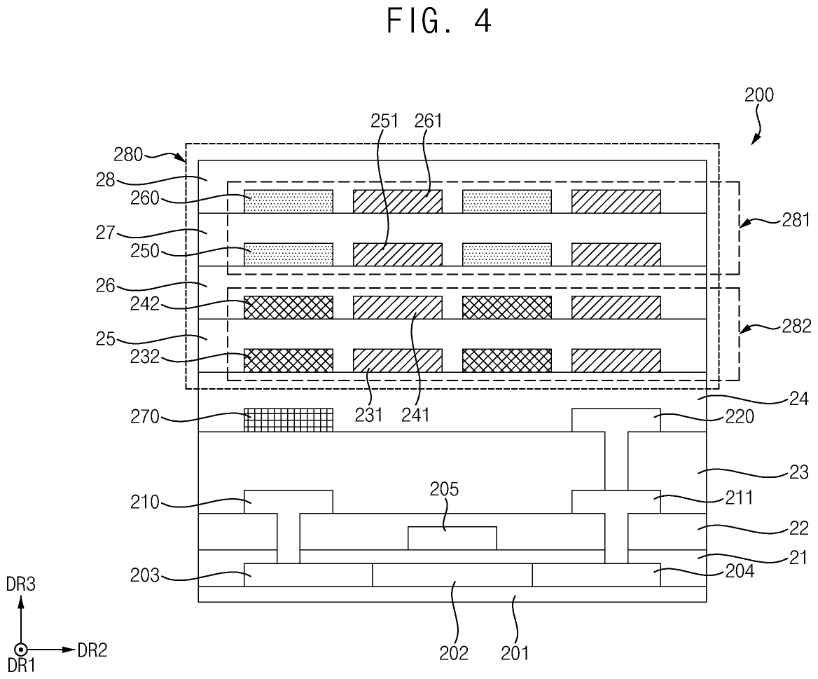

FIG. 4 is a cross-sectional view illustrating a sub-pixel for comparison.

Referring to FIG. 4, a display device 200 includes a substrate 201, active patterns 202, 203, and 204, a gate electrode 205, a first connection electrode 210, a second connection electrode 211, a third connection electrode 220, first electrode lines 250 and 260, second electrode lines 231, 241, 251, and 261, third electrode lines 232 and 242, a data line 270, a first insulating layer 21, a second insulating layer 22, a third insulating layer 23, a fourth insulating layer 24, a fifth insulating layer 25, a sixth insulating layer 26, a seventh insulating layer 27, and an eighth insulating layer 28.

The first electrode lines 250 and 260 include a 1-1 electrode line 250 and a 1-2 electrode line 260, the second electrode lines 231, 241, 251, and 261 include a 2-1 electrode line 231, a 2-2 electrode line 241, a 2-3 electrode line 251, and a 2-4 electrode line 261, and the third electrode lines 232 and 242 include a 3-1 electrode line 232 and a 3-2 electrode line 242.

As shown in FIG. 4, the first to eighth insulating layers 21, 22, 23, 24, 25, 26, 27, and 28 separate layers on which the active patterns 202, 203, and 204, the gate electrode 205, the first connection electrode 210, the second connection electrode 211, the third connection electrode 220, the first electrode lines 250 and 260, the second electrode lines 231, 241, 251, and 261, the third electrode lines 232 and 242, and the data line 270 are formed. Each of the first to eighth insulating layers 21, 22, 23, 24, 25, 26, 27, and 28 may be formed of an inorganic material or an organic material.

The substrate 201 may be a transparent resin substrate. Examples of the transparent resin substrate include a polyimide substrate, and the like. In this case, the polyimide substrate may include a first organic layer, a first barrier layer, a second organic layer, and the like. Optionally, the substrate 201 may include a quartz substrate, a synthetic quartz substrate, a calcium fluoride substrate, an F-doped quartz substrate, or soda lime glass, a non-alkali glass substrate, and the like. These may be used alone or in combination with each other.

The active patterns 202, 203, and 204 are disposed on the substrate 201.

The gate electrode 205 and the connection electrodes 210, 211, and 220 are disposed on the active patterns 202, 203, and 204.

In FIG. 4, the data line 270 is disposed on the same layer as the third connection electrode 220, and the data line 270 transfers a data signal to adjust a luminance of the display device 200.

The 1-1 electrode line 250, the 1-2 electrode line 260, the 2-3 electrode line 251, and the 2-4 electrode line 261 form a first capacitor 281.

The 2-1 electrode line 231, the 2-2 electrode line 241, the 3-1 electrode lines 232, and the 3-2 electrode line 242 form a second capacitor 282.

The first electrode lines 250 and 260, the second electrode lines 231, 241, 251, and 261, and the third electrode lines 232 and 242 forming the first capacitor 281 and the second capacitor 282 form MOM (metal-oxide-metal) capacitors.

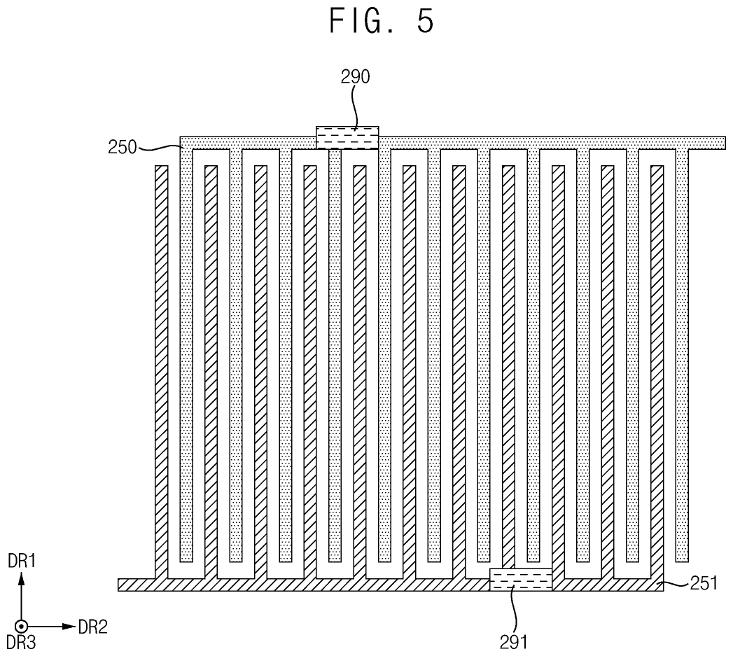

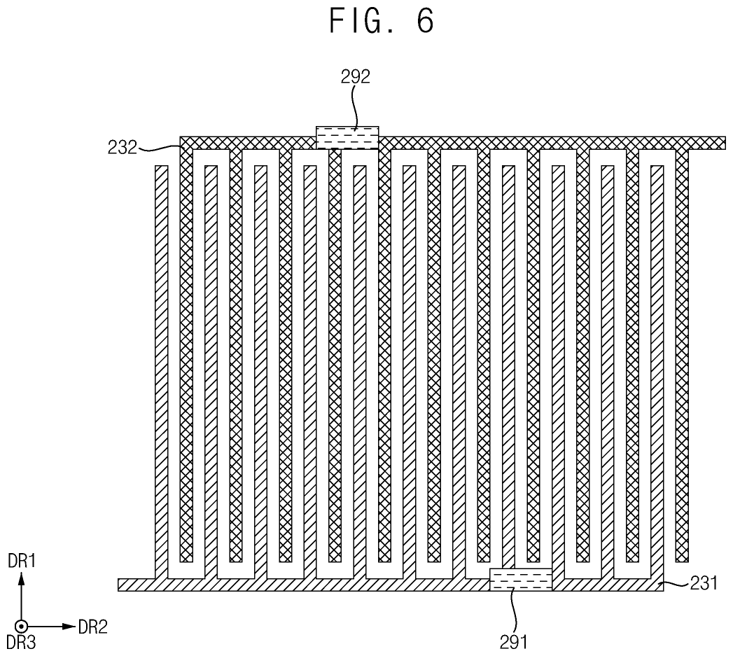

FIG. 5 is a plan view illustrating a 1-1 electrode line and a 2-3 electrode line included in the sub-pixel of FIG. 4 and FIG. 6 is a plan view illustrating a 2-1 electrode line and a 3-1 electrode line included in the sub-pixel of FIG. 4.

Referring to FIG. 5, the 1-1 electrode line 250 and the 2-3 electrode line 251 are interdigitated with the finger-like projections of the 1-1 electrode line 250 laced between finger-like projections of the 2-3 electrode line 251. Alternatively, each of the 1-1 electrode line 250 and the 2-3 electrode line 251 may have a serpentine shape, a repeated ‘S’ shape, or a zigzag shape, and each electrode line may be positioned to provide a long perimeter length adjacent to an electrode line corresponding to the opposite electrode of a capacitor. For example, the 1-1 electrode line 250 and the 2-3 electrode line 251 form the first capacitor 281.

Referring to FIG. 6, the 2-1 electrode line 231 and the 3-1 electrode line 232 are interdigitated with the finger-like projections of the 2-1 electrode line 231 laced between finger-like projections of the 3-1 electrode line 232. Alternatively, each of the 2-1 electrode line 231 and the 3-1 electrode line 232 may have a serpentine shape, an ‘S’ shape or a zigzag shape. Also, the 2-1 electrode line 231 and the 3-1 electrode line 232 form the second capacitor 282. However, a shape of the electrode lines is not limited to a shape shown in the drawing and may be arranged in various shapes.

In an embodiment, the 1-1 electrode line 250 and the 1-2 electrode line 260 have the same shape, and the 2-3 electrode line 251 and the 2-4 electrode line 261 have the same shape. Accordingly, an electrode line having the same shape as shown in FIG. 5 is formed on a layer above the 1-1 electrode line 250.

In an embodiment, the 3-1 electrode line 232 and the 3-2 electrode line 242 have the same shape, and the 2-1 electrode line 231 and the 2-2 electrode line 241 have the same shape. Accordingly, an electrode line having the same shape as shown in FIG. 6 is formed on a layer above the 3-1 electrode line 232.

At least one first via 290 electrically connects the first electrode lines 250 and 260. The second electrode lines 231, 241, 251, and 261 may be electrically connected through at least one second via 291, and the third electrode lines 232 and 242 may electrically connected through at least one third via 292. The electrically connected first, second, and third electrode lines share the same voltages, respectively. The first via 290, the second via 291, and the third via 292 may be collectively referred to as vias 290, 291, and 292.

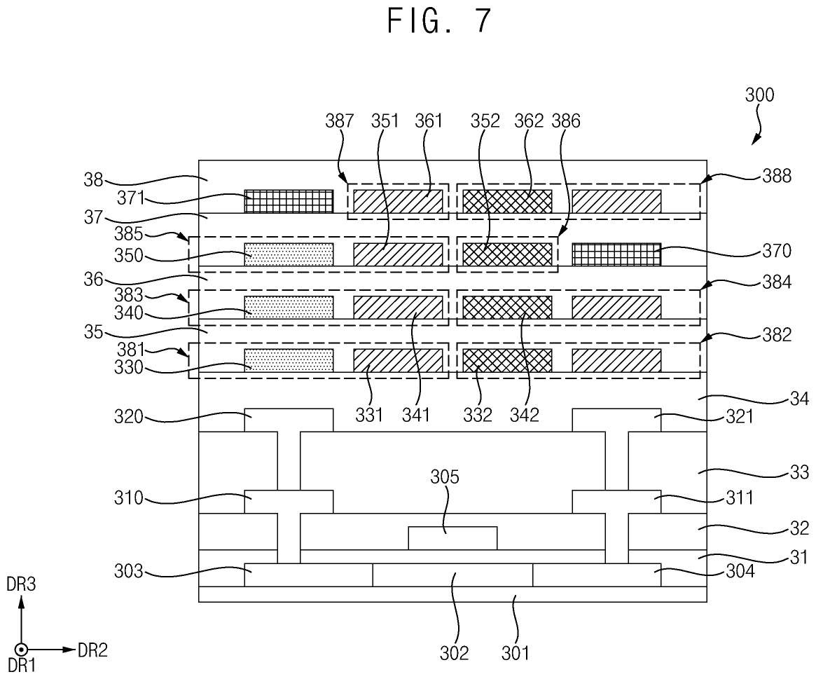

FIG. 7 is a cross-sectional view illustrating a portion of a sub-pixel that may be included in a display device 300 according to an embodiment of the present disclosure. The illustrated portion includes first capacitors 381, 383, 385, and 387 and second capacitors 382, 384, 386, and 388. The first capacitors 381, 383, 385, and 387 may include a 1-1 capacitor 381, a 1-2 capacitor 383, a 1-3 capacitor 385, and a 1-4 capacitor 387. The second capacitors 382, 384, 386, and 388 may include a 2-1 capacitor 382, a 2-2 capacitor 384, a 2-3 capacitor 386, and a 2-4 capacitor 388. In an embodiment, the 1-1 capacitor 381 and the 2-1 capacitor 382 may be formed on the same layer, and the 1-2 capacitor 383 and the 2-2 capacitor 384 may be formed on the same layer.

The display device 300 according to an embodiment illustrated in FIG. 7 may include a substrate 301, active patterns 302, 303, and 304, a gate electrode 305, connection electrodes 310, 311, 320, and 321, electrode lines 330, 331, 332, 340, 341, 342, 350, 351, 352, 361, and 362 forming the first capacitors 381, 383, 385, and 387 and the second capacitors 382, 384, 386, and 388, a first data line 370, a second data line 371, a first insulating layer 31, a second insulating layer 32, a third insulating layer 33, a fourth insulating layer 34, a fifth insulating layer 35, a sixth insulating layer 36, a seventh insulating layer 37, and an eighth insulating layer 38.

As shown in FIG. 7, the first to eighth insulating layers 31, 32, 33, 34, 35, 36, 37, and 38 may separate the layers on which the active patterns 302, 303, and 304, the gate electrode 305, the first to fourth connection electrodes 310, 311, 320, and 321, the electrode lines 330, 331, 332, 340, 341, 342, 350, 351, 352, 361, and 362 forming the capacitors 381 to 388, the first data line 370, and the second data line 371 are formed. Each of the first to eighth insulating layers 31, 32, 33, 34, 35, 36, 37, and 38 may be formed of an inorganic material or an organic material.

The substrate 301 may include a transparent material or an opaque material. For example, the substrate 301 may include a rigid glass substrate, a polymer substrate, a flexible film, a metal substrate, and the like. These may be used alone or in combination with each other. In an embodiment, the substrate 301 may include a rigid glass substrate.

The active patterns 302, 303, and 304 may be disposed on the substrate 301. The active patterns 302, 303, and 304 may include a metal oxide semiconductor, an inorganic semiconductor (e.g., amorphous silicon or poly silicon), an organic semiconductor, and the like. The active patterns 302, 303, and 304 may include a source region 303, a drain region 304, and a channel region 302 positioned between the source region 303 and the drain region 304.

The metal oxide semiconductor forming the active patterns 302, 303, and 304 may include a two-component compound (ABx), a three-component compound (ABxCy), a four-component compound (ABxCyDz) including indium (In), zinc (Zn), gallium (Ga), tin (Sn), titanium (Ti), aluminum (Al), hafnium (Hf), zirconium (Zr), magnesium (Mg), etc. For example, the metal oxide semiconductor may include zinc oxide (ZnOx), gallium oxide (GaOx), tin oxide (SnOx), indium oxide (InOx), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

Accordingly, a transistor including the gate electrode 305, the source region 303, and the drain region 304 may be disposed on the substrate 301.

The first connection electrode 310, the second connection electrode 311, the third connection electrode 320, and the fourth connection electrode 321 may be disposed on the transistor. For example, the first connection electrode 310 and the second connection electrode 320 may overlap and electrically connect to the source region 303, and the third connection electrode 311 and the fourth connection electrode 321 may overlap and electrically connect to the drain region 304.

The first electrode lines 330, 340, and 350, the second electrode lines 331, 341, 351, and 361, and the third electrode lines 332, 342, 352, and 362 may be disposed on the connection electrode 310, 311, 320, and 321 or formed in layers overlying the connection electrode 310, 311, 320, and 321. The first electrode lines 330, 340, and 350 may respectively include a 1-1 electrode line 330, a 1-2 electrode line 340, and a 1-3 electrode line 350. The second electrode lines 331, 341, 351, and 361 may respectively include a 2-1 electrode line 331, a 2-2 electrode line 341, a 2-3 electrode line 351, and a 2-4 electrode line 361. The third electrode lines 332, 342, 352, and 362 may respectively include a 3-1 electrode line 332, a 3-2 electrode line 342, a 3-3 electrode line 352, and a 3-4 electrode line 362.

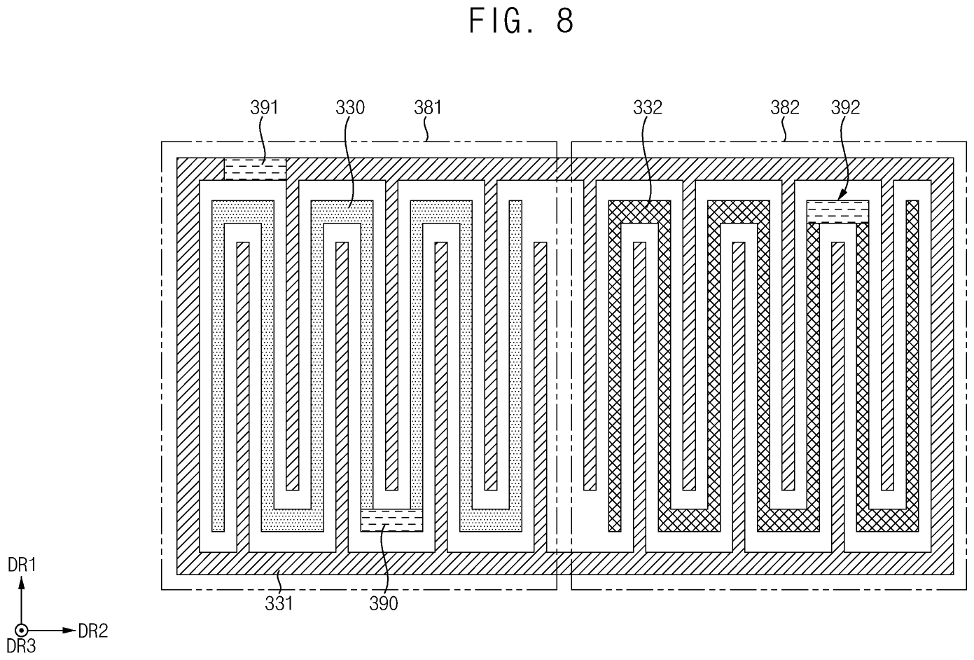

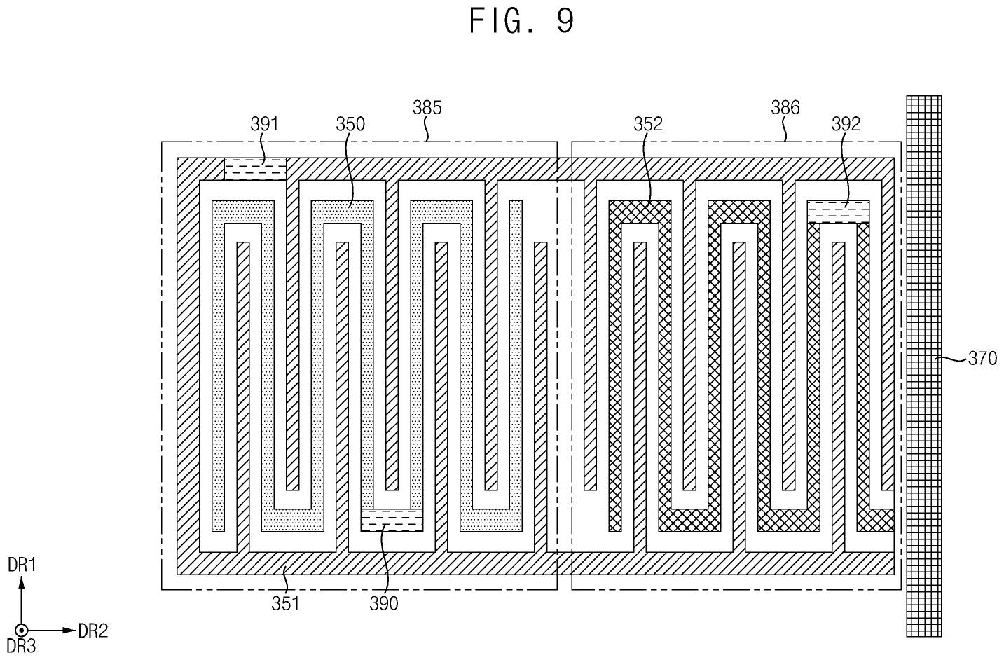

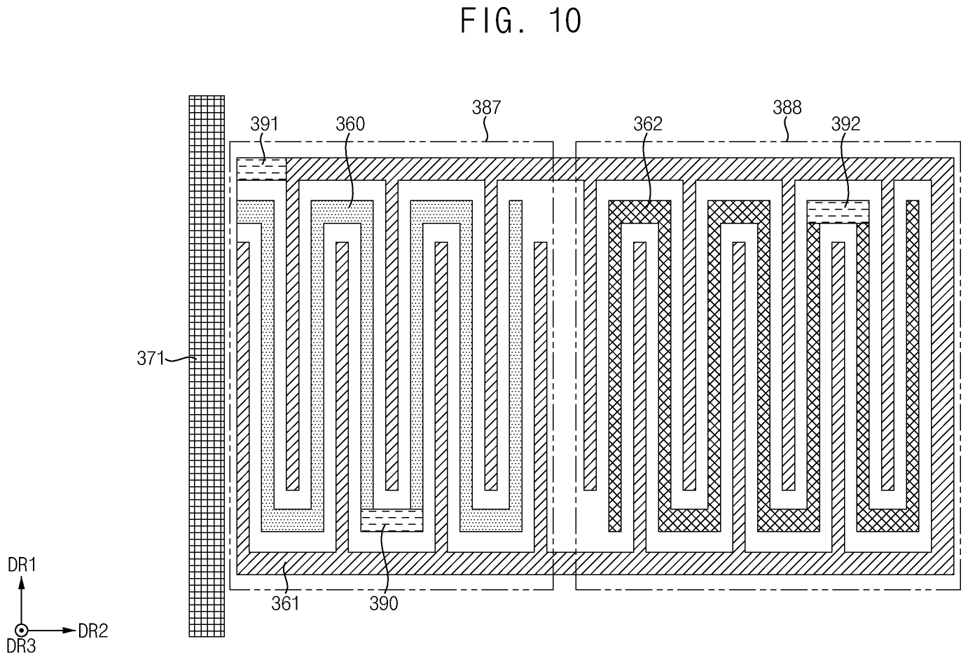

FIGS. 8, 9, and 10 show plan views of layers in which capacitors shown in FIG. 7 may be formed. In the layer shown in FIG. 8, the 1-1 electrode line 330 and the 2-1 electrode line 331 are adjacent to each other in an area and may form the 1-1 capacitor 381. In another layer having a layout similar to that shown in FIG. 8, the 1-2 electrode line 340 and the 2-2 electrode line 341 may form the 1-2 capacitor 383. In the layer shown in FIG. 9, the 1-3 electrode line 350 and the 2-3 electrode line 351 are adjacent to each other in an area and may form the 1-3 capacitor 385. In the layer shown in FIG. 10, a 1-4 electrode line 360 and the 2-4 electrode line 361 are adjacent to each other and may form the 1-4 capacitor 387. In another embodiment, the 1-1 electrode line 330 and the 1-2 electrode line 340 may form the MIM capacitor.

Also, in the layer shown in FIG. 8, the 2-1 electrode line 331 and the 3-1 electrode line 332 are adjacent to each other in an area and may form the 2-1 capacitor 382. The 2-2 electrode line 341 and the 3-2 electrode line 342 may have a similar layout and form the 2-2 capacitor 384. In the layer shown in FIG. 9, the 2-3 electrode line 351 and the 3-3 electrode line 352 are adjacent to each other in an area and may form the 2-3 capacitor 386, and in the layer shown in FIG. 10, the 2-4 electrode line 361 and the 3-4 electrode line 362 are adjacent to each other in an area and may form the 2-4 capacitor 388.

The 1-1, 1-2, 1-3, and 1-4 capacitors 381, 383, 385, and 387 may be connected in parallel to form a larger capacitor, e.g., capacitor CAP1 of FIG. 3, and the 2-1, 2-2, 2-3, and 2-4 capacitors 382, 384, 386, and 388 may be connected in parallel to form a larger capacitor having, e.g., capacitor CAP2 of FIG. 3. In particular, a via 390 may electrically connect the first electrode lines 330, 340, 350, and 360, a via 391 may electrically connect the second electrode lines 331, 341, 351, and 361, and a via 392 may electrically connect the third electrode lines 332, 342, 352, and 362. The connected electrode lines may have the same voltage by transmitting and receiving electrical signals through the via 390, 391, or 392 that connects the electrode lines. The vias 390, 391, and 392 may respectively include a first via 390, a second via 391, and a third via 392. In an embodiment, the electrode lines may be electrically connected to each other, for example, the 1-1 electrode line 330 may be electrically connected to the 1-2 electrode line 340 through the first via 390.

Each of the first capacitors 381, 383, 385, and 387 and the second capacitors 382, 384, 386, and 388 may be a MOM capacitor.

The first data line 370 may be disposed on the same layer as the 2-3 electrode line 351 as shown in FIG. 9. The second data line 371 may be disposed on a layer overlying the first data line 370 and may be disposed on the same layer as the 2-4 electrode line 361 as shown in FIG. 10. In another embodiment, the first data line 370 and the second data line 371 are not disposed on the same layers as the 2-3 electrode line 351 and the 2-4 electrode line 361 but may be disposed on various layers apart from the third connection electrode 320 and the fourth connection electrode 321 by one layer.

FIG. 8 is a plan view illustrating a 1-1 electrode line, a 2-1 electrode line, and a 3-1 electrode line included in the sub-pixel of FIG. 7.

Referring to FIG. 8, each of the 1-1 electrode line 330 and the 3-1 electrode line 332 may have a serpentine shape, a repeated ‘S’ shape, or a zigzag shape, and the 2-1 electrode may have projections that extend into folds within the shapes of the 1-1 electrode line 330 and the 3-1 electrode line 332. In addition, the 1-1 electrode line 330 and the 2-1 electrode line 331 may form the 1-1 capacitor 381, and the 2-1 electrode line 331 and the 3-1 electrode line 332 may form the 2-1 capacitor 382. However, embodiments are not limited to a specific shape or the plan view, and various types of MOM capacitors may be formed.

In an embodiment, the 1-1 electrode line 330 and the 1-2 electrode line 340 may have the same shape, the 2-1 electrode line 331 and the 2-2 electrode line 341 may have the same shape, and the 3-1 electrode line 332 and the 3-2 electrode line 342 may have the same shape. Accordingly, an electrode line having a shape shown in FIG. 8 may be formed on a layer above the 1-1 electrode line 330.

FIG. 9 is a plan view illustrating a 1-3 electrode line, a 2-3 electrode line, a 3-3 electrode line, and a first data line included in the sub-pixel of FIG. 7 and FIG. 10 is a plan view illustrating a 1-4 electrode line, a 2-4 electrode line, a 3-4 electrode line, and a second data line included in the sub-pixel of FIG. 7. As shown, each of the 1-3 electrode line 350, the 1-4 electrode line 360, the 2-3 electrode line 351, the 2-4 electrode line 361, the 3-3 electrode line 352, and the 3-4 electrode lines 362 may have a repeated ‘S’ shape or zigzag shape, and each electrode line may be interwoven or interleaved with an opposing electrode line to increase that capacitance that may be provided in an area. Also, the 1-3 electrode line 350 and the 2-3 electrode line 351 may form the 1-3 capacitor 385, the 2-3 electrode line 351 and the 3-3 electrode line 352 may form the 2-3 capacitor 386, the 1-4 electrode line 360 and the 2-4 electrode line 361 may form the first 1-4 capacitor 387, and the 2-4 electrode line 361 and the 3-4 electrode line 362 may form the 2-4 capacitor 388. However, embodiments are not limited to a specific shape of plan view, and various types of MOM capacitors may be formed.

In another embodiment, the first data line 370 and the second data line 371 are not formed only on the same layer as the 2-3 electrode line 351 and the 2-4 electrode line 361. The first data line 370 and the second data line 371 may be formed on various layers apart from the third connection electrode 320 and the fourth connection electrodes 320 by one layer.

FIG. 7 in which data lines are not in the same layer as a connection electrode to an electrode line layer, and this placement of the data lines may prevent formation of parasitic capacitors by reducing the interaction of the data lines with the gate electrode. Accordingly, the charging rate of the capacitors can be improved. In this case, a data line may be spaced apart from the connection electrode by at least one layer. Through this, pixels can be driven at high speeds while still providing a desired luminance in each pixel.

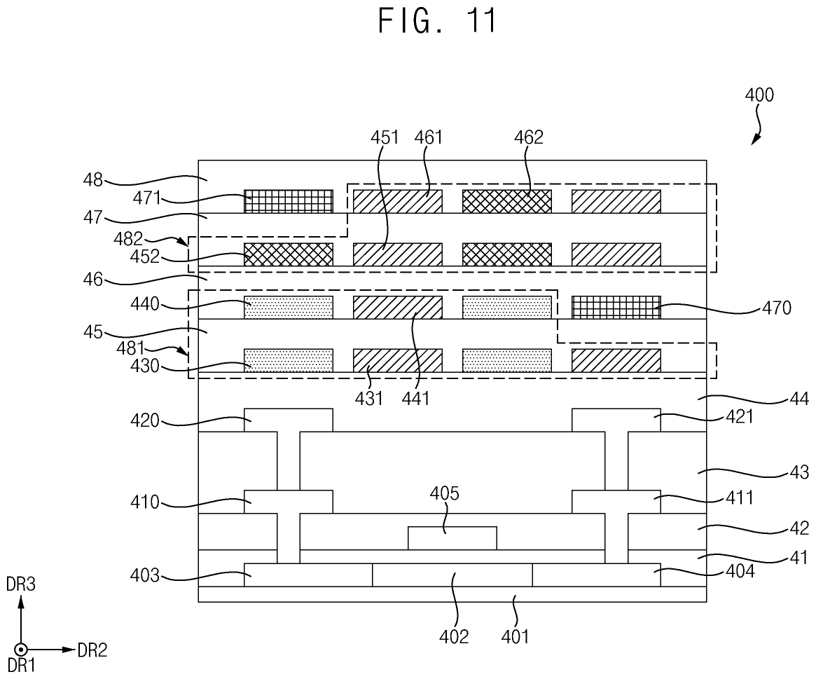

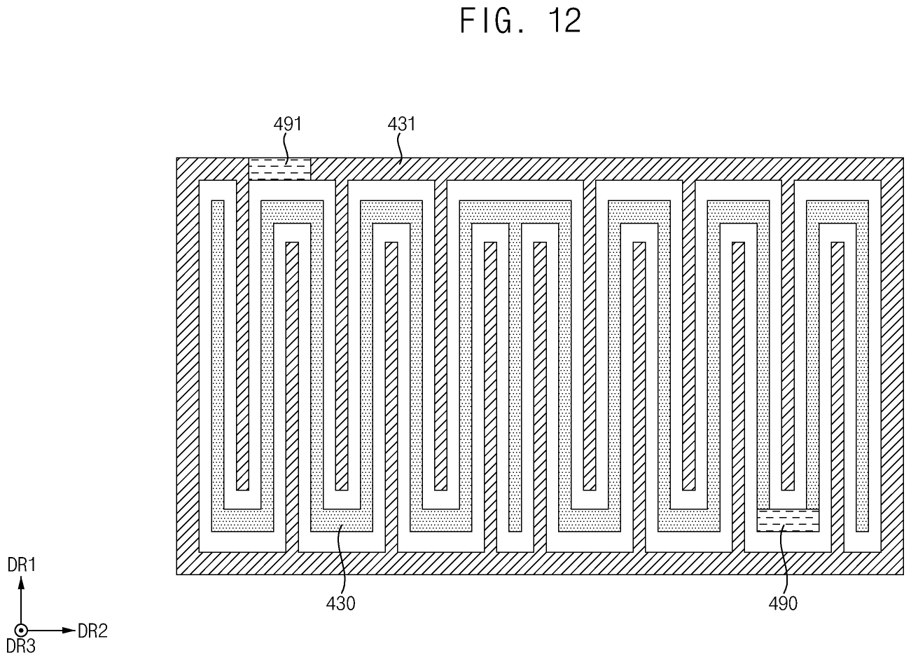

FIG. 11 is a cross-sectional view illustrating a portion of a sub-pixel included in a display device 400 according to another embodiment of the present disclosure. The display device 400 of FIG. 11 includes a sub-pixel in which a first capacitor 481 and a second capacitor 482 may be formed on different layers.

Referring to FIG. 11, the display device 400 may include a substrate 401, active patterns 402, 403, and 404, a gate electrode 405, and connection electrodes 410, 411, 420, and 421, electrode lines 430, 431, 440, 441, 451, 452, 461, and 462 forming the capacitors 481 and 482, a first data line 470 and a second data line 471, a first insulating layer 41, a second insulating layer 42, a third insulating layer 43, a fourth insulating layer 44, a fifth insulating layer 45, a sixth insulating layer 46, a seventh insulating layer 47, and an eighth insulating layer 48.

As shown in FIG. 11, the first to eighth insulating layers 41, 42, 43, 44, 45, 46, 47, and 48 may separate layers on which the active patterns 402, 403, and 404, the gate electrode 405, the first to fourth connection electrodes 410, 411, 420, and 421, the electrode lines 430, 431, 440, 441, 451, 452, 461, and 462, the first data line 470, and the second data line 471 are formed.

For example, each of the first to eighth insulating layers 41, 42, 43, 44, 45, 46, 47, and 48 may be formed of an inorganic material or an organic material.

The substrate 401 may include a transparent material or an opaque material. For example, the substrate 401 may include a rigid glass substrate, a polymer substrate, a flexible film, a metal substrate, and the like. These may be used alone or in combination with each other. In an embodiment, the substrate 401 may include a rigid glass substrate.

The active patterns 402, 403, and 404 may be disposed on the substrate 401. The active patterns 402, 403, and 404 may include a metal oxide semiconductor, an inorganic semiconductor (e.g., amorphous silicon or poly silicon), an organic semiconductor, and the like. The active patterns 402, 403, and 404 may include a source region 403, a drain region 404, and a channel region 402 positioned between the source region 403 and the drain region 404.

The metal oxide semiconductor forming active patterns 402, 403, and 404 may include a two-component compound (Abx), a three-component compound (AbxCy), a four-component compound (AbxCyDz) including indium (In), zinc (Zn), gallium (Ga), tin (Sn), titanium (Ti), aluminum (Al), hafnium (Hf), zirconium (Zr), magnesium (Mg), etc. For example, the metal oxide semiconductor may include zinc oxide (ZnOx), gallium oxide (GaOx), tin oxide (SnOx), indium oxide (InOx), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

The gate electrode 405 may overlie the channel region 404. Accordingly, a transistor including the gate electrode 405, the source region 403 and the drain region 404 and the channel region 402 may be disposed on the substrate 401.

The first connection electrode 410, the second connection electrode 411, the third connection electrode 420, and the fourth connection electrode 421 may be disposed on the transistor.

Portions of the first electrode lines 430 and 440, the second electrode lines 431, 441, 451, and 461, and the third electrode lines 452 and 462 may be disposed on the third connection electrode 420 and the fourth connection electrode 421.

The first electrode lines 430 and 440 may include a 1-1 electrode line 430 and a 1-2 electrode line 440. The second electrode lines 431, 441, 451, and 461 may include a 2-1 electrode line 431, a 2-2 electrode line 441, a 2-3 electrode line 451, and a 2-4 electrode line 461. The third electrode lines 452 and 462 may include a 3-1 electrode line 452 and a 3-2 electrode line 462.

The 1-1 electrode line 430, the 1-2 electrode line 440, the 2-1 electrode line 431, and the 2-2 electrode line 441 may form the first capacitor 481, and the 2-3 electrode line 451, the 2-4 electrode line 461, the 3-1 electrode line 452, and the 3-2 electrode line 462 may form the second capacitor 482. In other words, the 1-1 electrode line 430 and the 2-1 electrode line 431 may form a capacitor and the 1-2 electrode line 440 and 202 electrode line 441 may form another capacitor on a different layer, respectively. The 2-3 electrode line 451 and the 3-1 electrode line 452 may form a capacitor and the 2-4 electrode line 461 and 3-2 electrode line 462 may form another electrode line on a different layer, respectively. The first capacitor 481 and the second capacitor 482 may be MOM capacitors.

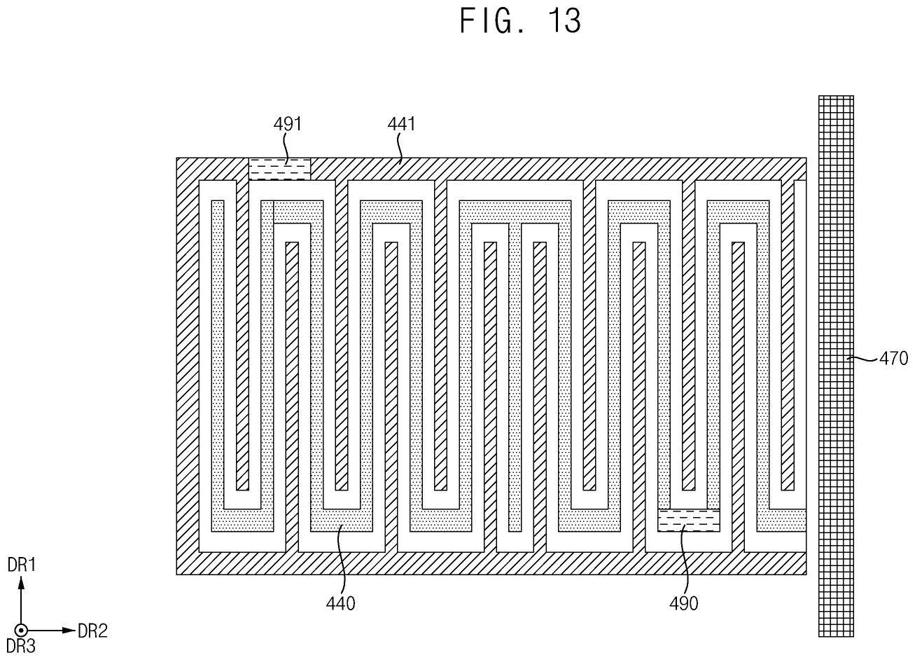

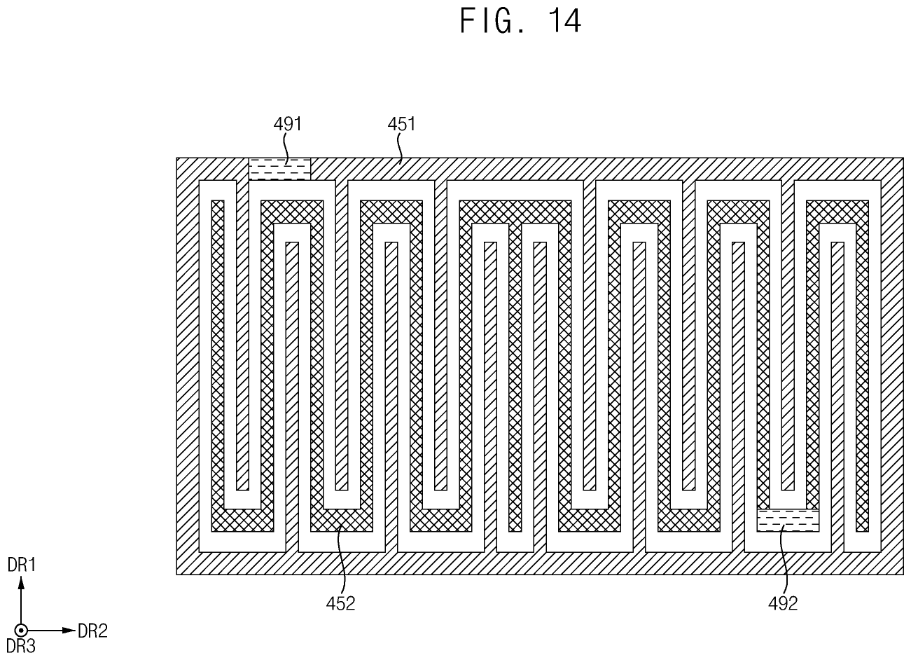

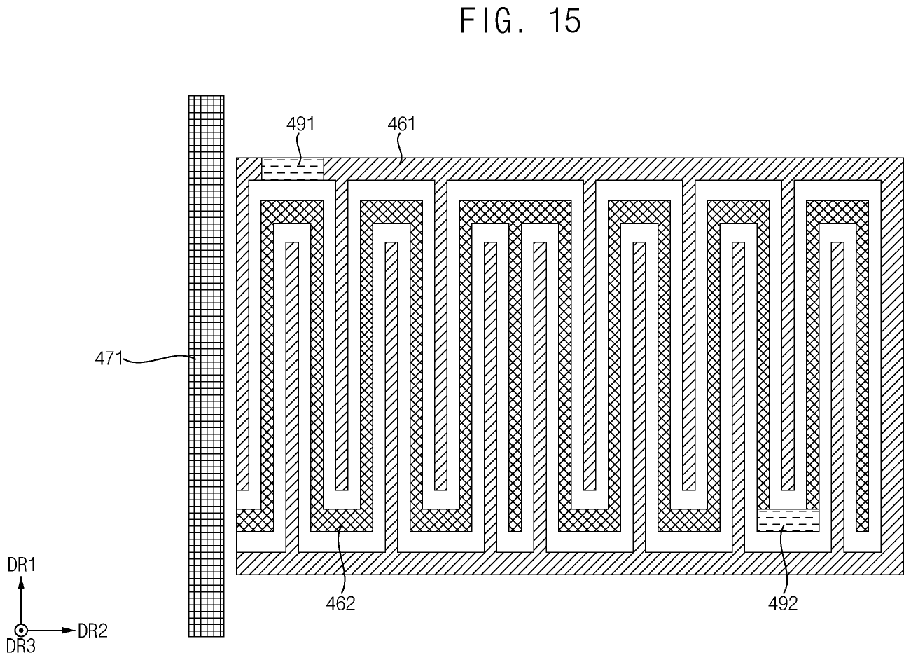

The first electrode lines 430 and 440 may be electrically connected through a via 490 shown in FIGS. 12 and 13. The second electrode lines 431, 441, 451, and 461 may be electrically connected through a via 491 shown in FIGS. 12 to 15, and the third electrode lines 452 and 462 may be electrically connected through a via 492 shown in FIGS. 14 and 15. The electrically-connected electrode lines may have the same voltage by transmitting and receiving electrical signals through the connecting via 490, 491, or 492. The vias 490, 491, and 492 may include a first via 490, a second via 491, and a third via 492.

The first data line 470 may be disposed on the same layer as the 1-2 electrode line 440. The second data line 471 may be disposed in a layer on or overlying the first data line 470 and may be disposed on the same layer as the 2-4 electrode lines 461. In another embodiment, the first data line 470 and the second data line 471 may not respectively disposed on the same layer as the 2-2 electrode line 441 and the 2-4 electrode line 461 but may be disposed on various layers separated from the third and the fourth connection electrodes 420 and 421 by at least one layer.

FIG. 12 is a plan view illustrating an embodiment of the 1-1 electrode line 430 and the 2-1 electrode line 431 included in the sub-pixel of FIG. 11, FIG. 13 is a plan view illustrating an embodiment of the 1-2 electrode line 440, the 2-2 electrode line 441, and the first data line 470 included in the sub-pixel of FIG. 11, FIG. 14 is a plan view illustrating an embodiment of the 2-3 electrode line 451 and the 3-1 electrode line 452 included in the sub-pixel of FIG. 11, and FIG. 15 is a plan view illustrating an embodiment of the 2-4 electrode line 461, the 3-2 electrode line 462, and the second data line 471 included in the sub-pixel of FIG. 11.

As shown in FIG. 12 and FIG. 13, the 1-1 electrode line 430, the 2-1 electrode line 431, the 1-2 electrode line 440, and the 2-2 electrode line 441 may form the first capacitor 481.

As shown in FIG. 14 and FIG. 15, the 2-3 electrode line 451, the 2-4 electrode line 461, the 3-1 electrode line 452, and the 3-2 electrode line 462 may form the second capacitor 482.

Also, each of the first electrode lines 430 and 440, the second electrode lines 431, 441, 451, and 461, and the third electrode lines 452 and 462 may have a serpentine shape, a repeated ‘S’ shape, a zigzag shape, or a digitated shape. Each of the electrode lines may generally be shaped and positioned to provide a long length of perimeter that is adjacent to the perimeter of another electrode line formed in the same layer. However, embodiments are not limited to a specific shape of the plan view, and various types of MOM capacitors may be formed.

As shown in FIG. 11, disposing existing data lines 470 and 471 in the same layer as an electrode line of a capacitor instead of in the same layer as a connection to a transistor, interaction with the gate electrode of the transistor may be reduced to prevent parasitic capacitor formation. Accordingly, a charging rate of the capacitor can be improved. In this case, a data line may be disposed apart from the connection electrode by one or more layers. Through this, it is possible to implement a desired luminance in each pixel when designing a high-speed driving pixel. However, the embodiment shown in FIG. 11, unlike FIG. 7, is characterized in that the first capacitor 481 is disposed in layers separated from the layers forming the second capacitor 482.

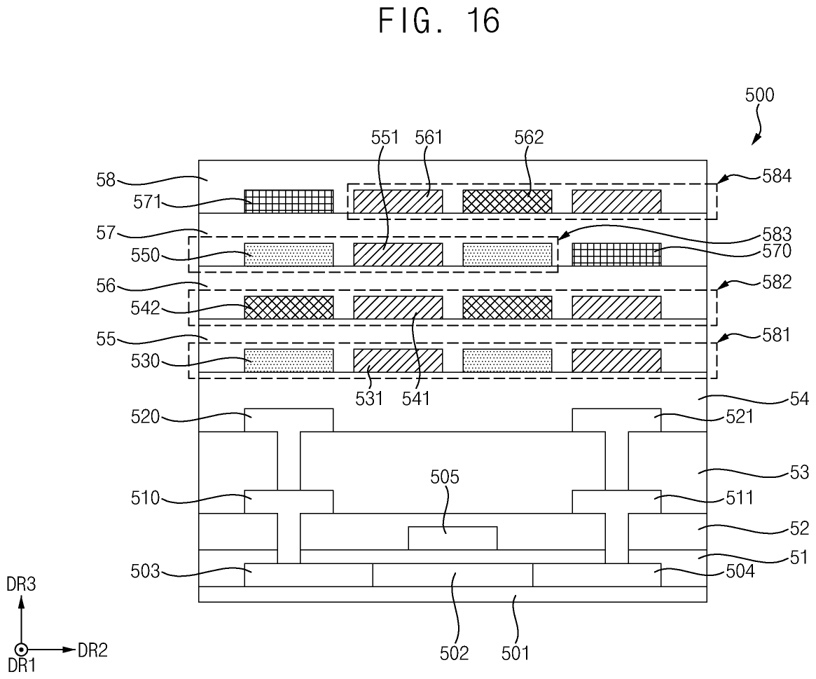

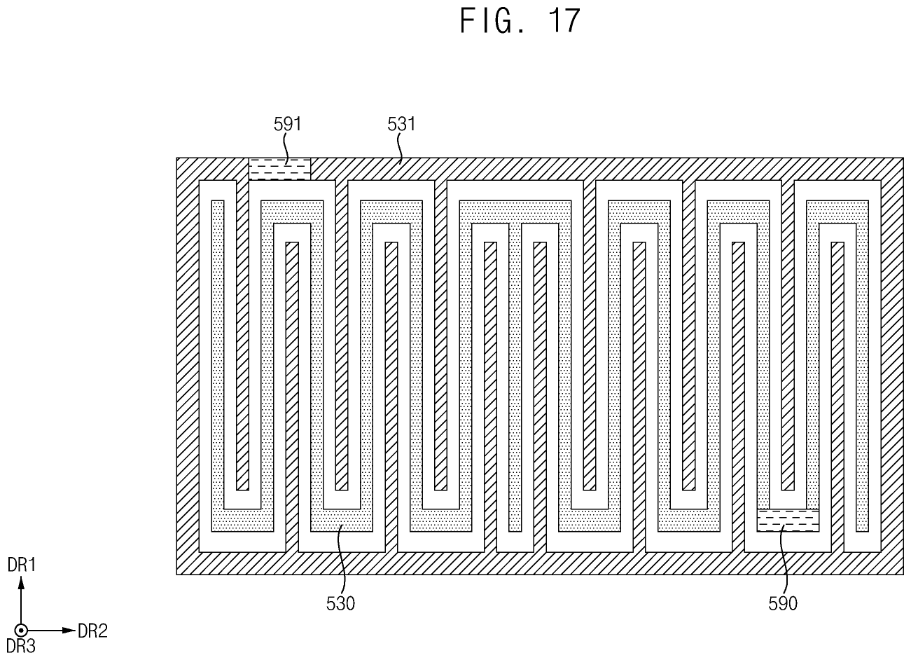

FIG. 16 is a cross-sectional view illustrating a portion of a sub-pixel included in a display device 500 according to still another embodiment of the present disclosure. In FIG. 16, the sub-pixel has first capacitors 581 and 583 and second capacitors 582 and 584 with an alternative arrangement in different layers.

The first capacitors 581 and 583 may include a 1-1 capacitor 581 and a 1-2 capacitor 583, and the second capacitors 582 and 584 may include a 2-1 capacitor 582 and a 1-2 capacitor 584. In an embodiment, the 2-1 capacitor 582 may be formed on the 1-1 capacitor 581, and the 1-2 capacitor 583 may be formed on the 2-1 capacitor 582.

Referring to FIG. 16, the display device 500 may include a substrate 501, active patterns 502 and 503, and 504, a gate electrode 505, connection electrodes 510, 511, 520, and 521, electrode lines 530, 531, 541, 542, 550, 551, 561, and 562, a first data line 570, a second data line 571, a first insulating layer 51, a second insulating layer 52, a third insulating layer 53, a fourth insulating layer 54, a fifth insulating layer 55, a sixth insulating layer 56, a seventh insulating layer 57, and an eighth insulating layer 58.

As shown in FIG. 16, the first to eighth insulating layers 51, 52, 53, 54, 55, 56, 57, and 58 may separate layers on which the active patterns 502, 503, and 504, the gate electrode 505, the connection electrodes 510, 511, 520, and 521, the electrode lines 530, 531, 541, 542, 550, 551, 561, and 562 forming the first capacitors 581 and 583 and the second capacitors 582 and 584, the first data line 570, and the second data line 571 are formed.

For example, each of the first to eighth insulating layers 51, 52, 53, 54, 55, 56, 57, and 58 may be formed of an inorganic material or an organic material.

The substrate 501 may include a transparent material or an opaque material. For example, the substrate 501 may include a rigid glass substrate, a polymer substrate, a flexible film, a metal substrate, and the like. These may be used alone or in combination with each other. In an embodiment, the substrate 501 may include a rigid glass substrate.

The active patterns 502, 503 and 504 may be disposed on the substrate 501. The active patterns 502, 503, and 504 may include a metal oxide semiconductor, an inorganic semiconductor (e.g., amorphous silicon or poly silicon), an organic semiconductor, and the like. The active patterns 502, 503, and 504 may include a source region 503, a drain region 504, and a channel region 502 positioned between the source region 503 and the drain region 504.

The metal oxide semiconductor used in active patterns 502, 503, and 504 may include a two-component compound (ABx), a three-component compound (ABxCy), a four-component compound (ABxCyDz) including indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOx), gallium oxide (GaOx), tin oxide (SnOx), indium oxide (InOx), indium gallium oxide (IGO), indium zinc oxide (IZO), indium tin oxide. (ITO), indium zinc tin oxide (IZTO), indium gallium zinc oxide (IGZO), and the like. These may be used alone or in combination with each other.

A transistor including the gate electrode 505, the source region 503, the drain region 504, and the channel region 502 may be disposed on the substrate 501.

The first connection electrode 510, the second connection electrode 511, the third connection electrode 520, and the fourth connection electrode 521 may be disposed on the transistor.

The first electrode lines 530 and 550, the second electrode lines 531, 541, 551, and 561, and the third electrode lines 542 and 562 may be formed in layers overlying the third connection electrode 520 and the fourth connection electrode 521.

The first electrode lines 530 and 550 may include a 1-1 electrode line 530 and a 1-2 electrode line 550. The second electrode lines 531, 541, 551, and 561 may include a 2-1 electrode line 531, a 2-2 electrode line 541, a 2-3 electrode line 551, and a 2-4 electrode line 561. The third electrode lines 542 and 562 may include a 3-1 electrode line 542 and a 3-2 electrode line 562.

The 1-1 electrode line 530 and the 2-1 electrode line 531 may form the 1-1 capacitor 581, and the 2-2 electrode line 541 and the 3-1 electrode line 542 may form the 2-1 capacitor 582. In addition, the 1-2 electrode line 550 and the 2-3 electrode line 551 may form the 1-2 capacitor 583, and the 2-4 electrode line 561 and the 3-2 electrode line 562 may form the 2-2 capacitor 584.

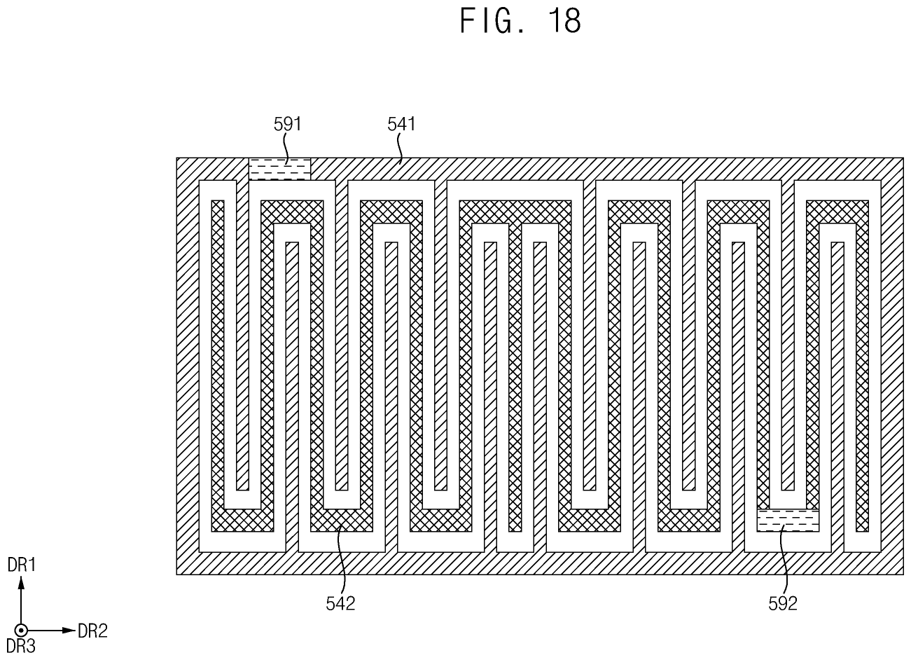

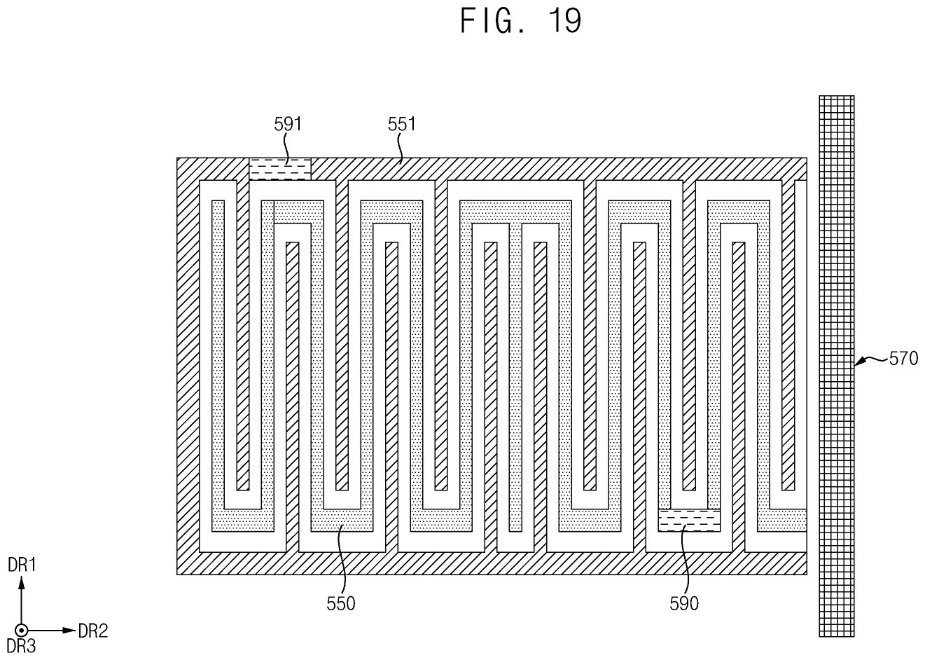

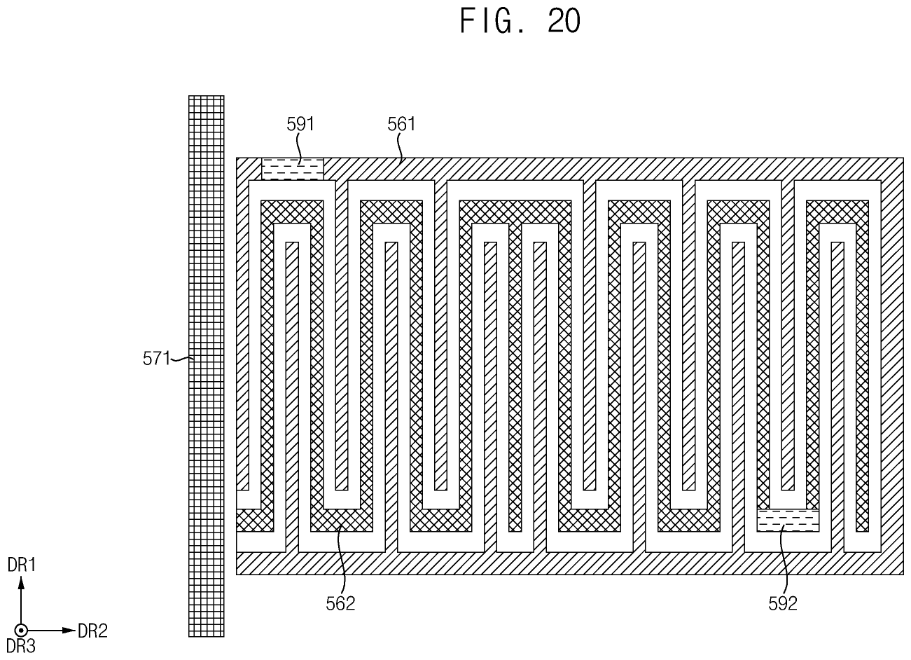

A via 590 shown in FIGS. 17 and 19 may electrically connect the first electrode lines 530 and 550. A via 591 shown in FIGS. 17 to 20 may electrically connect the second electrode lines 531, 541, 551, and 561, and a via 592 shown in FIGS. 18 and 20 may electrically connect the third electrode lines 542 and 562. The electrically connected electrode lines may have the same voltage by transmitting and receiving electrical signals through the via 590, 591, or 592. The vias 590, 591, and 592 may include a first via 590, a second via 591, and a third via 592.

The first capacitors 581 and 583 and the second capacitors 582 and 584 may be MOM capacitors. Also, in the display device 500, the first capacitors 581 and 583 and the second capacitors 582 and 584 may be disposed on different layers. In an embodiment, the 2-1 capacitor 582 may be formed on the 1-1 capacitor 581, and the 1-2 capacitor 583 may be formed on the 2-1 capacitor 582.

The first data line 570 may be disposed on the same layer as the 2-3 electrode line 551. The second data line 571 may be disposed on the first data line 570 and may be disposed on the same layer as the 2-4 electrode line 561. However, in another embodiment, the first and second data lines 570 and 571 may not be formed only on the same layer as the 2-3 electrode line 551 and the 2-4 electrode line 561 but may be formed on various layers apart from the connection electrodes 520 and 521 by one layer.

FIG. 17 is a plan view illustrating a 1-1 electrode line 530 and a 2-1 electrode line 531 included in the sub-pixel of FIG. 16, FIG. 18 is a plan view illustrating a 2-2 electrode line 542 and a 3-1 electrode line 541 included in the sub-pixel of FIG. 16, FIG. 19 is a plan view illustrating a 1-2 electrode line 550, a 2-3 electrode line 551, and a first data line 570 included in the sub-pixel of FIG. 16, and FIG. 20 is a plan view illustrating a 2-4 electrode line 561, a 3-2 electrode line 562, and a second data line 571 included in the sub-pixel of FIG. 16.

Also, each of the first electrode lines 530 and 550, the second electrode lines 531, 541, 551, and 561, and the third electrode lines 542 and 562 may have a serpentine shape, a repeated ‘S’ shape, a zigzag shape, or a digitated shape. Each of the electrode lines may be positioned or arranged to interlace with another electrode line form in the same layer. However, embodiments are not limited to a specific shape of the plan view, and various types of MOM capacitors may be formed.

As shown in FIG. 16, by disposing data lines in the same layer as an electrode line, the interaction with the gate electrode of an underlying transistor may be reduced to prevent a formation of parasitic capacitors. Accordingly, a charging rate of the capacitor can be improved. In this case, the data line may be disposed apart from the connection electrode by one or more layers. Through this, each pixel in a display device can implement a desired luminance when driven at high speed. However, the embodiment of FIG. 16 differs from the embodiment of FIG. 11 in that the first capacitor and the second capacitor may be formed on different layers and alternately formed.

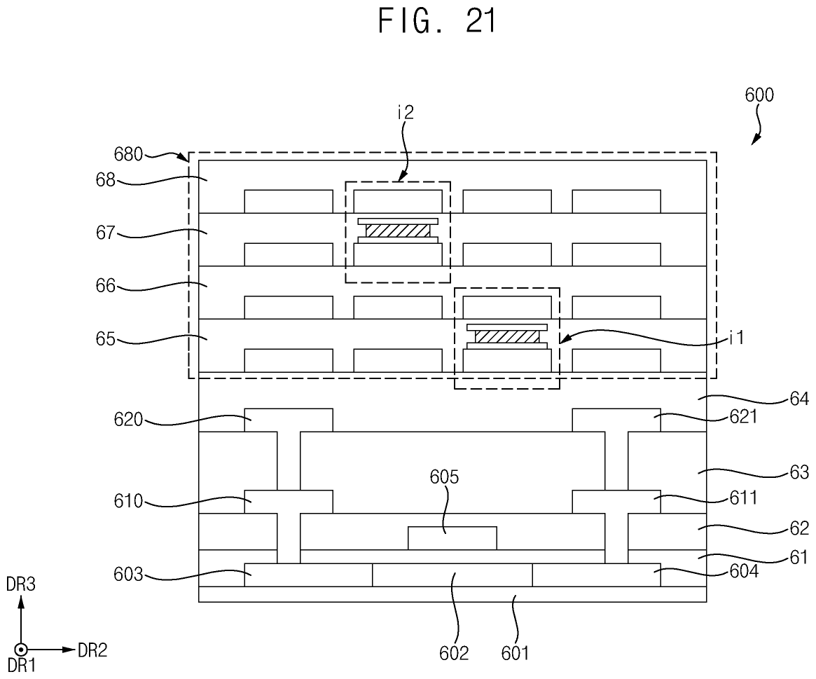

FIG. 21 is a cross-sectional view illustrating a portion of a sub-pixel included in a display device 600 according to another embodiment.

The display device 600 may include a substrate 601, active patterns 602, 603, and 604, a gate electrode 605, connection electrodes 610, 611, 620, and 621, a first MIM capacitor i1, a second MIM capacitor i2, a capacitor forming unit 680, a first insulating layer 61, a second insulating layer 62, a third insulating layer 63, a fourth insulating layer 64, a fifth insulating layer 65, a sixth insulating layer 66, a seventh insulating layer 67, and an eighth insulating layer 68.

As shown in FIG. 21, the first to eighth insulating layers 61, 62, 63, 64, 65, 66, 67, and 68 may separate layers on which the active patterns 602, 603, and 604, the gate electrode 605, the connection electrodes 610, 611, 620, and 621, the first MIM capacitor i1, the second MIM capacitor i2 and capacitor forming part 680 are formed.

For example, each of the first to eighth insulating layers 61, 62, 63, 64, 65, 66, 67, and 68 may be formed of an inorganic material or an organic material.

The substrate 601 may include a transparent material or an opaque material.

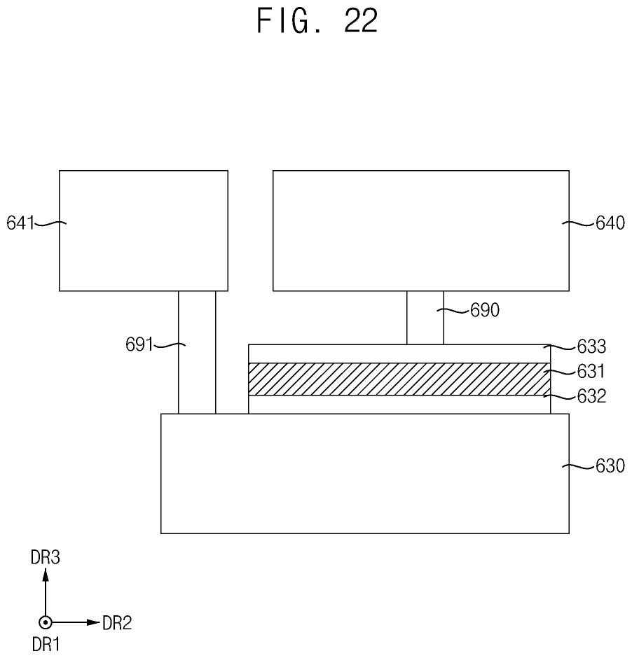

FIG. 22 is an enlarged view illustrating structure for the first and second MIM capacitors i1 and i2 included in the sub-pixel of FIG. 21.

The MIM capacitor is formed with an insulating layer 631 inserted between a lower metal 632 and an upper metal 633. The lower metal 632 is on an electrode 630.

The lower metal 632 may be electrically connected to the upper electrode line 641 by contacting the lower electrode line 630 through a via 691. Also, the upper metal 633 may be electrically connected to an upper electrode line 640 through a via 690.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
an active pattern disposed on a substrate;
a gate electrode disposed on the active pattern;
a first connection electrode disposed on and connected to the active pattern;
a first electrode line disposed on the first connection electrode;
a second electrode line disposed on a same layer as the first electrode line and forming a first capacitor with the first electrode line;
a third electrode line disposed on the same layer as the first electrode line and forming a second capacitor with the second electrode line;
a first data line disposed on the third electrode line; and
a second data line spaced apart from the first data line.

2. The display device of claim 1, wherein the first data line and the second data line are on different layers.

3. The display device of claim 2, wherein no electrode line is disposed on the second data line.

4. The display device of claim 3, wherein no electrode line is disposed between the first data line and the second data line.

5. The display device of claim 1, further comprising:
a fourth electrode line disposed on the first electrode line, and
wherein a MIM capacitor between the first electrode and the fourth electrode line is formed.

6. A display device comprising:
an active pattern disposed on a substrate;
a gate electrode disposed on the active pattern;
a first connection electrode disposed on and connected to the active pattern;
a 1-1 electrode line disposed on the first connection electrode;
a 2-1 electrode line disposed on a same layer as the 1-1 electrode line and forming a first capacitor with the 1-1 electrode line;
a first data line disposed on the 2-1 electrode line;
a 3-1 electrode line disposed on the first data line;
a 2-3 electrode line disposed on a same layer as the 3-1 electrode line and forming a second capacitor with the 3-1 electrode line; and
is a second data line disposed on the 2-3 electrode line.

7. The display device of claim 6, further comprising:
a 1-2 electrode line disposed on the 1-1 electrode line and electrically connected to the 1-1 electrode line; and
a 2-2 electrode line disposed on the 2-1 electrode line, electrically connected to the 2-1 electrode line, and forming a third capacitor with the 1-2 electrode line, the third capacitor being connected in parallel with the first capacitor.

8. The display device of claim 7, wherein the first data line is disposed on a same layer as the 2-2 electrode line.

9. The display device of claim 6, further comprising
a 3-2 electrode line disposed on the 3-1 electrode line and electrically connected to the 3-1 electrode line; and
a 2-4 electrode line disposed on the 2-3 electrode line, electrically connected to the 2-3 electrode line, and forming a fourth capacitor with the 3-2 electrode line, the fourth capacitor being connected in parallel with the second capacitor.

10. The display device of claim 9, wherein the second data line is disposed on a same layer as the 2-4 electrode line.

11. The display device of claim 6, further comprising:
a MIM capacitor between the 1-1 electrode line and the 1-2 electrode line.

12. A display device comprising:
an active pattern disposed on a substrate;
is a gate electrode disposed on the active pattern;
a first connection electrode disposed on and connected to the active pattern;
a 1-1 electrode line disposed on the first connection electrode;
a 2-1 electrode line disposed on a same layer as the 1-1 electrode line and forming a 1-1 capacitor with the 1-1 electrode line;
a 3-1 electrode line disposed on the 1-1 electrode line;
a 2-2 electrode line disposed on a same layer as the 3-1 electrode line, electrically connected to the 2-1 electrode, and forming a 2-1 capacitor with the 3-1 electrode line;
a first data line disposed on the 3-1 electrode line; and
a second data line disposed apart from the first data line.

13. The display device of claim 12, wherein the first data line and the second data line are on different layers.

14. The display device of claim 13, wherein no electrode line is disposed on the second data line.

15. The display device of claim 14, wherein no electrode line is formed on a layer between the second data line and the first data line.

16. The display device of claim 12, further comprising:
is a 1-2 electrode line disposed on the 1-1 electrode line and electrically connected to the 1-1 electrode line; and
a 2-3 electrode line disposed on the 2-1 electrode line and electrically connected to the 2-1 electrode line,
wherein the 1-2 electrode line and the 2-3 electrode line form a 1-2 capacitor.

17. The display device of claim 16, wherein the first data line is formed on a same layer as the 1-2 electrode line.

18. The display device of claim 12, further comprising:
a 3-2 electrode line disposed on the 3-1 electrode line and electrically connected to the 3-1 electrode line; and
a 2-4 electrode line disposed on the 2-2 electrode line and electrically connected to the 2-2 electrode line,
wherein the 3-2 electrode line and the 2-4 electrode line form a 2-2 capacitor.

19. The display device of claim 18, wherein the second data line is formed on a same layer as the 3-2 electrode line.

20. The display device of claim 12, further comprising:
a MIM capacitor between the 1-1 electrode line and the 3-1 electrode line.
